(19) United States
(12) Patent Application Publication
(10) Pub. No.: US 2009/0139571 A1
(43) Pub. Date: Jun. 4, 2009

(54) SOLAR CELL AND MANUFACTURING METHOD THEREOF

(75) Inventors: Chii-Chang CHEN, Taoyuan Hsien (TW); Chia-Hua Chan, Taoyuan Hsien (TW); Huang-Nan Wu, Taoyuan Hsien (TW); Fu-Yuan Yao, Taoyuan Hsien (TW); Sheng-Hui Chen, Taoyuan Hsien (TW); Hung-Chien Shieh, Taoyuan Hsien (TW); Cheng-Chung Lee, Taoyuan Hsien (TW); Tai-Kang Shing, Taoyuan Hsien (TW)

Correspondence Address: Muncy, Geissler, Olds & Lowe, PLLC, P.O. BOX 1364, FAIRFAX, VA, 22038-1364, US

(73) Assignees: DELTA ELECTRONICS, INC.; NATIONAL CENTRAL UNIVERSITY

(21) Appl. No.: 12/168,569

(22) Filed: Jul. 7, 2008

(30) Foreign Application Priority Data
Nov. 30, 2007 (TW) 96145567

(51) Int. Cl. H01L 31/0376; H01L 31/18

(52) U.S. Cl. 136/258; 438/96; 257/E31.047

(57) ABSTRACT

A solar cell and a manufacturing method thereof are provided herein. The solar cell includes a substrate with a first transparent conductive layer, a micro- or nano-roughing structure formed on the first transparent conductive layer, and a semiconductor active layer formed on the micro- or nano-roughing structure and covering the micro- or nano-roughing structure.

### CROSS REFERENCE TO RELATED APPLICATIONS

This Application claims priority of Taiwan Patent Application No. 096145567, filed on Nov. 30, 2007, the entirety of which is incorporated by reference herein.

### BACKGROUND OF THE INVENTION

1. Field of the Invention

The present invention relates to a solar cell and method for fabricating the same, and in particular relates to a solar cell having a micro- or nano-roughing structure in between the substrate and the semiconductor layer so as to increase photo-electricity transformation of the solar cell.

2. Description of the Related Art

Currently, about 90 percent of solar cells are produced from silicon wafers. However, in recent years, due to lack of silicon raw materials, thin-film solar cells which do not use silicon raw materials or reduce the quantity thereof, have been developed. Nevertheless, currently, silicon-based solar cells are mainly produced. As for thin-film solar cells, tandem cells are mainly being developed for efficient sunlight energy absorption and usage.

FIG. 1 is a schematic view of a conventional thin-film solar cell. The thin-film solar cell 1 includes a silver metal layer 11, a first transparent conductive oxide 12, a micro-silicon layer 13, an amorphous silicon layer 14, a second transparent conductive layer 15 and a glass substrate 16 The average thicknesses of the micro-silicon 13 and the amorphous silicon 14 are respectively between 1.5 μm and 2.0 μm and 0.2 μm and 0.3 μm for best sunlight energy absorption.

As for the tandem cell, because the tandem cell uses two kinds of materials (micro-silicon and amorphous silicon), the light absorption wave band is broader than a solar cell made of a single amorphous silicon material. The micro-silicon and amorphous silicon materials allow a light absorption wave band range from visible light to infrared light, to improve sunlight absorption efficiency and completeness.

However, after the amorphous silicon material is irradiated by sunlight for a long period of time (called like the light deterioration phenomenon), the interior of the amorphous silicon material will become defective and result in decreased light absorption efficiency of the solar cells. As for the micro-silicon material, a relatively thick film is required for sunlight absorption efficiency of a long wave band, due to the lower absorption coefficient of light for the material. Thus, increasing manufacturing time and costs.

Consequently, if film thickness were to be reduced and light absorption efficiency kept for the micro-silicon material, it would reduce manufacturing time and costs. Additionally, it would achieve a better quality thin-film along with increased manufacturing efficiency of fabricated products. However, if the thickness of the film is lower than the minimal thickness for efficient sunlight absorption, the absorption coefficient of sunlight may become deficient and result in decreased absorption efficiency.

### BRIEF SUMMARY OF THE INVENTION

The invention provides a solar cell and method for fabricating the same. The invention reduces semiconductor layer thickness, while keeping light absorption efficiency and completeness.

To achieve the above-described goals, an exemplary embodiment of the solar cell comprises a substrate having a first transparent conductive layer. A micro- or nano-roughing structure is formed on the first transparent conductive layer and a semiconductor layer is formed on the micro- or nano-roughing structure and covers the micro-nanomicro- or nano-roughing structure. The micro- or nano-roughing structure formed by a plurality of micro- or nano-particles comprises silicon oxide (SiO₂), titanium oxide (TiO₂), zinc oxide (ZnO₂), polystyrene or polymethylmethacrylate (PMMA), wherein the micro- or nano-particles comprise between 50 nm and 1000 nm, and the micro- or nano-particles have a uniform size or different sizes.

To achieve the above-described goals, a method for fabricating a solar cell is provided. An exemplary embodiment of a method for fabricating a solar cell comprises providing a substrate. Next, a micro- or nano-roughing structure is formed on the substrate. And next, a semiconductor layer is formed on the micro- or nano-roughing structure and covers the micro- or nano-roughing structure. The step for forming the micro- or nano-roughing structure is performed by dipping, spraying, spin-coating, natural drying, stacking, burning, nano-imprinting, imprinting or hot-pressing, and the micro- or nano-roughing structure is adhered on the substrate. The micro- or nano-roughing structure is formed by a plurality of micro- or nano-particles.

The invention of a solar cell and method for fabricating the same is based on the conventional silicon thin-film solar cell. The micro- or nano-roughing structure is inserted into the semiconductor layer (such as silicon film) and the upper electrode (such as Transparent Conductive Oxide, TCO) to increase the optical path, raising the absorption efficiency of the silicon thin-film and reduce the minimal thickness of the silicon thin-film so as to improve the efficient usage of the amorphous silicon material, reduce the light degradation of amorphous silicon material and decrease manufacturing time of the micro-silicon material, thus decreasing material and manufacturing costs.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic view of a conventional thin-film solar cell.

FIG. 2 is a flow chart of an exemplary embodiment of a method for fabricating a solar cell.

FIGS. 3A to 3D show cross sections of each process step according to FIG. 2.

FIG. 4 illustrates a cross section of another exemplary embodiment of a solar cell.

FIG. 5 is a schematic view of coating the micro- or nano-particles by a stirring apparatus of a preferred embodiment of the present invention.

FIG. 6 is a flow chart of coating the micro- or nano-particles on the substrate.

FIGS. 7A to 7B show diagrams of a scanning electron microscope (SEM) of an exemplary embodiment of the present invention.

FIG. 8 illustrates curve diagrams comparing absorption efficiency of different thickness of silicon thin-films disposed on SiO₂ nano spheres with different size.

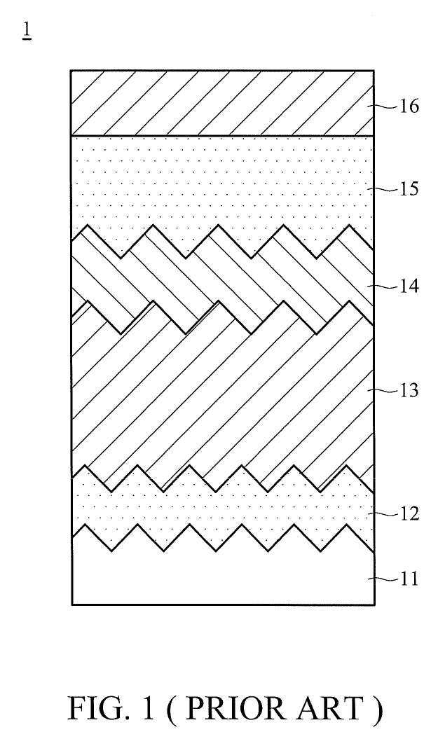

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The following description is of a solar cell and a manufacturing method thereof and is the best-contemplated mode of the invention.

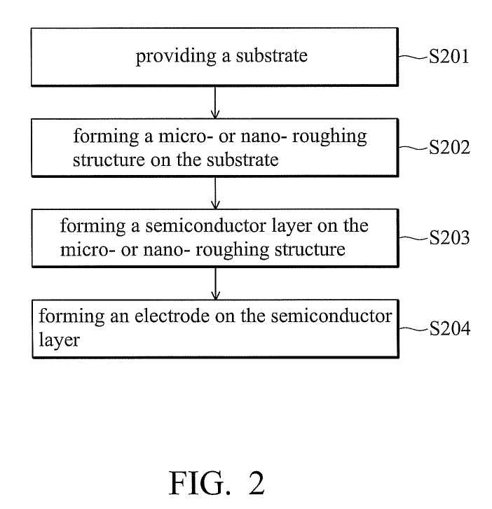

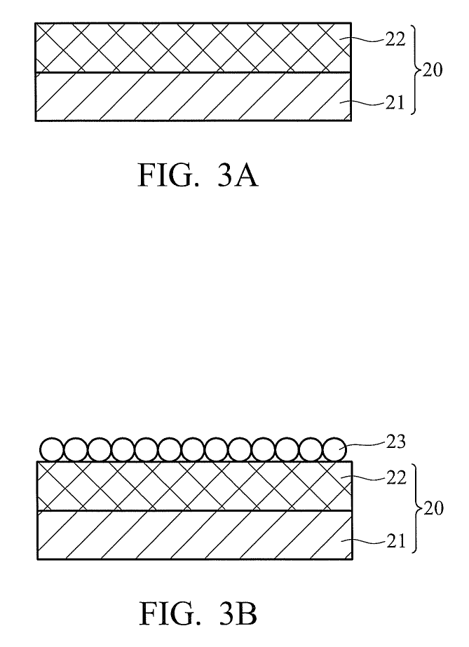

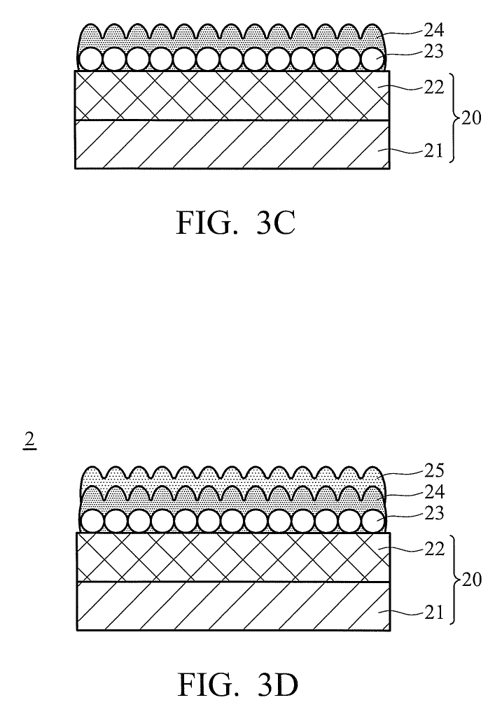

FIG. 2 is a flow chart of an exemplary embodiment of a method for fabricating a solar cell. FIGS. 3A to 3D show cross sections of each process step according to FIG. 2.

First, referring to FIG. 3A, a substrate 20 is provided, which is a transparent substrate 21 with a first transparent conductive layer 22 (step S201). The transparent substrate 21 may be, but is not limited to a glass substrate. The first transparent conductive layer 22 may be, but is not limited to a transparent conductive oxide (TCO), such as indium tin oxide (ITO). In addition, the surface structure of the first transparent conductive layer 22 is a textured or smooth structure.

Next, referring to FIG. 3B, a micro- or nano-roughing structure 23 is formed on the first transparent conductive layer 22 (step S202). The micro- or nano-roughing structure 23 is adhered on the first transparent conductive layer 22 by way of dipping, spraying, spin-coating, natural drying, stacking, burning, nano-imprinting, imprinting, or hot-pressing. The micro- or nano-roughing structure 23 is a spherical, pillar, particle, nano-pore, nano-point, nano-line, a structure with an irregular concave-convex surface, a periodical or non-periodical structure. In this exemplary embodiment, the micro- or nano-roughing structure 23, formed by a plurality of micro- or nano-particles, may comprise silicon oxide (SiO₂), titanium oxide (TiO₂), zinc oxide (ZnO₂), polystyrene or polymethylmethacrylate (PMMA). The sizes of the plurality of micro- or nano-particles are preferably between 50 nm and 1000 nm. Also, the micro- or nano-particles have a uniform size or different sizes.

Next, referring to FIG. 3C, a semiconductor layer 24 is formed on the micro- or nano-roughing structure 23 (step S203) and covers the micro- or nano-roughing structure 23 for performing photo-electricity transformation. Because the micro- or nano-roughing structure 23 has pores, the semiconductor layer 24 may cover the micro- or nano-roughing structure 23 and contact the first transparent conductive layer 22, thus allowing electrical power to flow by way of the first transparent conductive layer 22. The semiconductor layer 24 is a semiconductor active layer which may be a silicon film layer or a compound semiconductor layer. The silicon film layer may comprise amorphous silicon, micro-silicon, or amorphous silicon/micro-silicon stacked material. The compound semiconductor layer may comprise copper indium gallium selenium (CIGS/CIS) or tellurium cadmium (CdTe) but is not limited thereof. The semiconductor layer has an average thickness between 75 nm and 2500 nm.

Then, referring to FIG. 3D, an electrode 25 is formed on the semiconductor layer 24 (step S204). The electrode 25 may be a single metal layer, or a double layer formed by a second transparent conductive layer followed by forming of a metal layer (not shown).

Still referring to FIG. 3D, the solar cell 2 may include a substrate 20 having a first transparent conductive layer 22, a micro- or nano-roughing structure 23 formed on the first transparent conductive layer 22, a semiconductor layer 24 formed on the micro- or nano-roughing structure 23 and covering a plurality of the micro- or nano-roughing structure 23, and an electrode 25 formed on the semiconductor layer 24. The solar cell 2 may be a thin-film solar cell.

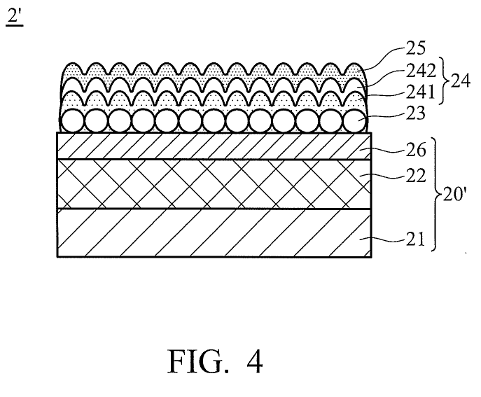

FIG. 4 illustrates a cross section of another exemplary embodiment of a solar cell, and the same portions with the above exemplary embodiment are omitted for brevity. The substrate 20′ of the solar cell 2′ is a transparent substrate 21 with the first transparent conductive layer 22 and a p-type semiconductor layer 26. The first transparent conductive layer 22 and the p-type semiconductor layer 26 are subsequently formed on the transparent substrate 21. The micro- or nano-roughing structure 23 is then formed on the p-type semiconductor layer 26. In this exemplary embodiment, the materials of the micro- or nano-roughing structure 23 may comprise silicon-based semiconductor, silicon carbide, silicon nitride or silicon germanium, and the micro- or nano-roughing structure 23 may be formed by a plurality of micro- or nano-particles. Then, the semiconductor layer 24 is formed on the micro- or nano-roughing structure 23, wherein the semiconductor layer 24 may comprise an un-doped intrinsic semiconductor layer 241 and an n-type semiconductor layer 242 subsequently formed on the micro- or nano-roughing structure 23. The micro- or nano-roughing structure 23 and the un-doped intrinsic semiconductor layer 241 have different band gap so as to perform photo-electricity transformation of sunlight with different wavelengths. An electrode 25 is then formed on the semiconductor layer 24.

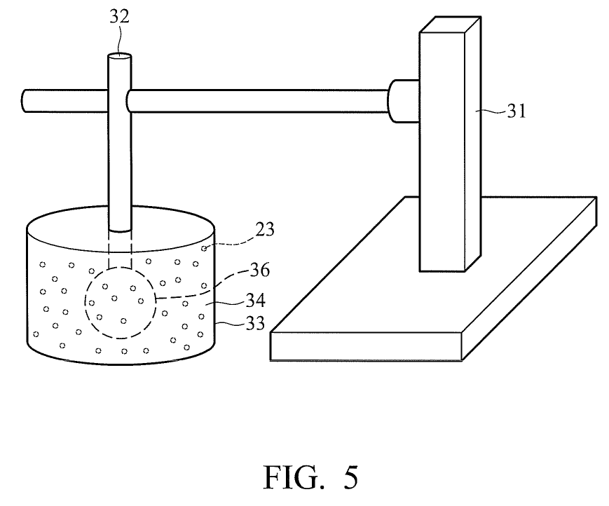

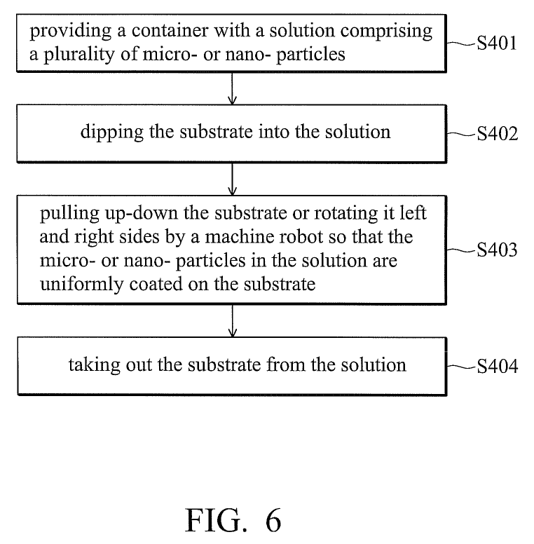

In the preferred embodiment of the present invention, the micro- or nano-roughing structure 23 is formed by a plurality of micro- or nano-particles. FIG. 5 is a schematic view of coating the micro- or nano-particles by a stirring apparatus of a preferred embodiment of the present invention. A stirring apparatus 3 includes an operation interface 31, a robot 32 and a container 33. FIG. 6 is a flow chart of coating the micro- or nano-particles on the substrate.

First, a container 33 with a solution 34 comprising a plurality of micro- or nano-particles 35 is provided (step S401). The plurality of micro- or nano-particles 35 are made by Sol-gel, emulsion polymerization, non-emulsion polymerization, suspension polymerization, reverse micelle or hot soap.

Then, a substrate 36 is dipped into the solution 34 (step S402). The substrate 36 is the substrate 20 or the substrate 20′ as described previously.

The substrate 36 is then pulled up and down or rotated left and right by the robot 32 in the solution 34 so that the micro- or nano-particles 35 in the solution 34 are uniformly coated on the substrate 36 (step S403), wherein setting conditions include a pulled rate of the substrate 36, sizes (diameters) of the micro- or nano-particles 35, a concentration of the micro- or nano-particles 35, a material of the micro- or nano-particles 35, a setting temperature of the solution 34 or an added solvent. The preferable pulled rate is between 0.5 mm/sec and 5 mm/sec. The sizes of the plurality of micro- or nano-particles are preferably, but are not limited to between 50 nm and 1000 nm. Also, the micro- or nano-particles have a uniform size or different sizes.

After, the substrate 36 is taken out from the solution 34 (step S404).

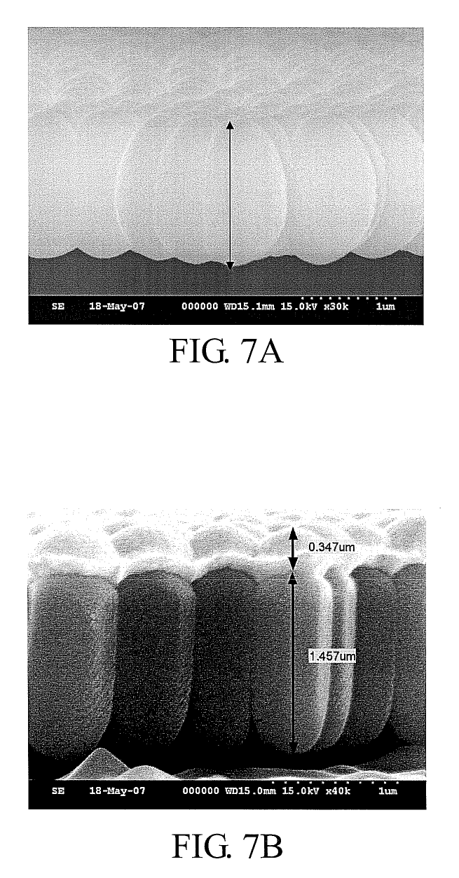

FIGS. 7A to 7B show diagrams of a scanning electron microscope (SEM) of the exemplary embodiment of the present invention. A preferable result of the embodiment is follows. In this embodiment, a plurality of SiO₂ nano sphericity are formed on the glass substrate by way of dipping, spraying, spin-coating, natural drying, stacking, burning, nano-imprinting, imprinting, or hot-pressing. The glass substrate is placed into a deposition machine and respectively deposited amorphous silicon and micro-silicon. SiO₂ nano sphericity in the silicon thin-film structure is grown from 600 nm to 1.6 μm by the thin-film disposition process. The silicon thin-film is successfully deposited on SiO₂ nano sphericity by the silicon deposition processes. Refer to FIG. 7A for the SEM diagrams. A comb-shaped electrode is then made on the surface of the silicon thin-film. The comb-shaped electrode is made of aluminum. As shown in FIG. 7B, the solar cell structure having the comb-shaped electrode may be successfully made with SiO₂ nano sphericity substrate.

The substrate described above with the disposed silicon thin-film on SiO₂ nano sphericity was placed in an integral ball to be analyzed so as to confirm light absorption characteristics of the embodiment.

According to the method described above, different sized SiO₂ nano sphericity micro- or nano-particles, such as 100 nm, 250 nm, 400 nm or 600 nm used in the amorphous silicon film disposition process of 100 nm, 250 nm, 400 nm or the micro-silicon film process of 500 nm. Through integral ball analysis, when comparing absorption efficiency of amorphous silicon film with nano sphericity and silicon film without nano sphericity, the preferred maximum absorption efficiency of amorphous silicon film with nano sphericity exceeded 12%, and when comparing absorption efficiency of micro-silicon film with nano sphericity and silicon film without nano sphericity, the preferred maximum absorption efficiency of micro-silicon film with nano sphericity exceeded 18%

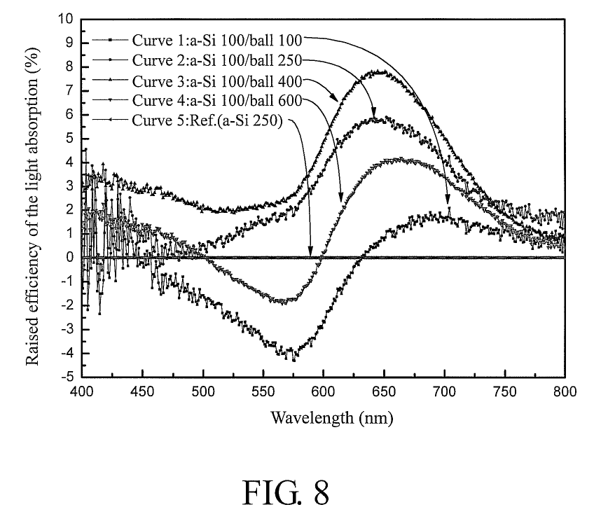

FIG. 8 illustrates curve diagrams comparing absorption efficiency of different disposed SiO₂ nano spherical thicknesses for silicon thin-films. The horizontal axis is wavelength and the vertical axis is raised efficiency of light absorption. Curve 1 is 100 nm amorphous silicon thin-film formed on 100 nm SiO₂ nano sphericity, curve 2 is 100 nm amorphous silicon thin-film formed on 250 nm SiO₂ nano sphericity, curve 3 is 100 nm amorphous silicon thin-film formed on 400 nm SiO₂ nano sphericity, curve 4 is 100 nm amorphous silicon thin-film formed on 600 nm SiO₂ nano sphericity, and curve 5 is 250 nm amorphous silicon thin-film formed directly on the substrate.

Referring to FIG. 8, 100 nm amorphous silicon thin-film formed on SiO₂ nano sphericity is compared with 250 nm amorphous silicon thin-film formed without SiO₂ nano sphericity. The results show that the absorption efficiency of the 100 nm amorphous silicon (a-Si) thin-film formed on 250 nm or 400 nm SiO₂ nano sphericity, was equal to, or better than the absorption efficiency of the 250 nm amorphous silicon thin-film formed without SiO₂ nano sphericity. Thus, showing that SiO₂ nano sphericity may raise the absorption efficiency of silicon thin-films, and absorption efficiency of solar cells do not have to decrease due to reduced silicon thin-film thickness, wherein the thinner silicon thin-film may raise the absorption efficiency.

The exemplary embodiment of the solar cell and manufacturing method thereof is based on the conventional silicon thin-film solar cell, wherein an SiO₂ nano sphericity nano-particle layer is inserted between the semiconductor layer (such as silicon film) and an electrode (such as Transparent Conductive Oxide, TCO) for increasing the optical path, raising the absorption efficiency of the silicon thin-film and reducing the minimal thickness of the silicon thin-film so that the light inferior quality of a-Si is reduced, the deposition time of micro-silicon is reduced, and material and manufacturing costs are reduced. Alternatively, the micro- or nano-particles are formed between the p-type semiconductor layer and the un-doped intrinsic semiconductor layer, thus raising the light absorption efficiency of the un-doped intrinsic semiconductor layer, and reducing the minimal absorption thickness. In addition, the un-doped intrinsic semiconductor layer and the micro- or nano-particles have different band gap so as to perform photo-electricity transformation of sunlight with different wavelengths.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell, comprising:
a substrate having a first transparent conductive layer;
a micro- or nano-roughing structure formed on the first transparent conductive layer; and
a semiconductor layer formed on the micro- or nano-roughing structure for covering the micro- or nano-roughing structure.

2. The solar cell as claimed in claim 1, wherein the micro- or nano-roughing structure is a spherical, pillar, particle, nano-pore, nano-point, nano-line, a structure with an irregular concave-convex surface, or a periodical or non-periodical structure.

3. The solar cell as claimed in claim 1, wherein the micro- or nano-structure comprises a plurality of micro- or nano-particles.

4. The solar cell as claimed in claim 3, wherein a material of the micro- or nano-particles comprise silicon oxide (SiO₂), titanium oxide (TiO₂), zinc oxide (ZnO₂), polystyrene or polymethylmethacrylate (PMMA).

5. The solar cell as claimed in claim 3, wherein the micro- or nano-particles have a particle size between 50 nm and 1000 nm, and the micro- or nano-particles have a uniform size or different sizes.

6 The solar cell as claimed in claim 4, wherein the semiconductor layer is a silicon film layer or a compound semiconductor layer, and the silicon film layer comprises an amorphous silicon, micro-silicon, or amorphous silicon/micro-silicon stacked material, and the compound semiconductor layer comprises copper indium gallium selenium (CIGS/CIS) or tellurium cadmium (CdTe).

7. The solar cell as claimed in claim 1, wherein the semiconductor layer has an average thickness ranging from 75 nm to 2500 nm.

8. The solar cell as claimed in claim 1, wherein the substrate comprises a transparent substrate or a glass substrate.

9. The solar cell as claimed in claim 1, further comprising an electrode formed on the semiconductor layer, or comprising a second transparent conductive layer and an electrode formed on the semiconductor layer in sequence.

10. The solar cell as claimed in claim 1, wherein the first transparent conductive layer comprises a transparent conductive oxide (TCO) or indium tin oxide (ITO).

11. The solar cell as claimed in claim 1, wherein the first transparent conductive layer has a texture or smooth surface structure.

12. The solar cell as claimed in claim 1, further comprising a p-type semiconductor layer formed between the micro- or nano-roughing structure and the first transparent conductive layer.

13. The solar cell as claimed in claim 12, wherein the semiconductor layer comprises an un-doped intrinsic semiconductor layer and an n-type semiconductor layer on the micro- or nano-roughing structure.

14. The solar cell as claimed in claim 13, wherein the micro- or nano-roughing structure comprises silicon-based semiconductor, silicon carbide, silicon nitride or silicon germanium, and the micro- or nano-roughing structure comprises a plurality of micro- or nano-particles.

15. A method for fabricating a solar cell, comprising the steps of:
providing a substrate;
forming a micro- or nano-roughing structure on the substrate; and
forming a semiconductor layer on the micro- or nano-roughing structure.

16. The method as claimed in claim 15, further comprising forming an electrode on the semiconductor layer.

17. The method as claimed in claim 15, wherein the step for forming the micro- or nano-roughing structure on the substrate is performed by dipping, spraying, spin-coating, natural drying, stacking, burning, nano-imprinting, imprinting or hot-pressing, and the micro- or nano-roughing structure is adhered on the first transparent conductive layer.

18. The method as claimed in claim 15, wherein the step for forming the micro- or nano-roughing structure on the substrate comprises a plurality of micro- or nano-particles on the substrate, and the micro- or nano-particles comprise silicon oxide (SiO2), titanium oxide (TiO2), zinc oxide (ZnO2), polystyrene, polymethylmethacrylate (PMMA) silicon-based semiconductor, silicon carbide, silicon nitride or silicon germanium.

19. The method as claimed in claim 18, wherein the substrate is a transparent substrate with a first transparent conductive layer and a p-type semiconductor layer, and the first transparent conductive layer and the p-type semiconductor layer are on the transparent substrate in sequence.

20. The method as claimed in claim 18, wherein the semiconductor layer comprising an un-doped intrinsic semiconductor layer and an n-type semiconductor layer is formed on the micro- or nano-roughing structure.

21. The method as claimed in claim 18, wherein the steps of forming the micro- or nano-particles on the substrate, further comprise the steps of:
providing a container with a solution comprising a plurality of micro- or nano-particles;
dipping the substrate with a first transparent conductive layer into the solution;
pulling the substrate up and down or rotating the substrate left and right in the solution so that the micro- or nano-particles in the solution are uniformly coated on the substrate; and
taking out the substrate from the solution.

22. The method for fabricating a solar cell as claimed in claim 21, wherein the micro- or nano-particles are manufactured by sol-gel, emulsion polymerization, non-emulsion polymerization, suspension polymerization, reverse micelle or hot soap.

23. The method for fabricating a solar cell as claimed in claim 21, wherein the setting conditions of the step for forming the micro- or nano-particles on the substrate comprise a pulled rate of the substrate, diameters of the micro- or nano-particles, a concentration of the micro- or nano-particles, a material of the micro- or nano-particles, a setting temperature of the solution or an added solvent.

24. The method for fabricating a solar cell as claimed in claim 23, wherein the pulled rate of the substrate is between 0.5 mm/sec and 5 mm/sec, and the sizes of the micro- or nano-particles are between 50 nm and 1000 nm.

25. The method for fabricating a solar cell as claimed in claim 21, wherein the step of forming the micro- or nano-particles on the substrate is performed by a stirring apparatus.
